(19) United States
(12) Patent Application Publication
(10) Pub. No.: US 2016/0272820 A1
(43) Pub. Date: Sep. 22, 2016

(54) CONDUCTIVE ALUMINUM PASTE FOR LOCAL BACK SURFACE FIELD SOLAR CELL AND SOLAR CELL REQUIRING THE CONDUCTIVE ALUMINUM PASTE

(71) Applicant: PANCOLOUR INK CO., LTD., Taoyuan County (TW)

(72) Inventors: HSIANG-MING HSUEH, TAOYUAN COUNTY (TW); YU-CHING PAI, TAOYUAN COUNTY (TW)

(21) Appl. No.: 14/661,472

(22) Filed: Mar. 18, 2015

(51) Int. Cl. C09D 5/24; H01L 31/0224

(52) U.S. Cl. CPC C09D 5/24; H01L 31/022441

(57) ABSTRACT

A conductive aluminum paste for a local back surface field solar cell includes an aluminum powder; an organic carrier including a resin and a solvent; and a vanadium oxide. A solar cell which includes the conductive aluminum paste is further provided. Both the conductive aluminum paste and the solar cell enhance the photoelectric conversion efficiency of the local back surface field solar cell and the pulling strength even though its lead content is reduced or it is lead-free.

### FIELD OF THE INVENTION

The present invention relates to conductive aluminum pastes, and more particularly, to a vanadium oxide-containing conductive aluminum paste. The present invention further relates to a solar cell requiring the conductive aluminum paste.

### BACKGROUND OF THE INVENTION

A solar cell is a device for converting sunlight into output DC power. In this regard, silicon solar cells dominate solar power generation (and account for at least 80% of the throughput thereof). Conventional products produced by related manufacturers mostly have a substrate made of p-type silicon, wherein the n⁺ emitter is formed on the light-receiving side of the substrate by high-temperature phosphorous diffusion, so as to form a p-n junction diode. Then, an anti-reflection layer 60˜80 nm thick is formed on the n⁺ surface. Afterward, a front busbar and a slender gridlike silver electrode 30˜90 μm thick are formed on the anti-reflection layer by screen printing, whereas a back busbar is also formed on the other side (p-side) by screen printing, and then an aluminum paste is formed thereon to function as an aluminum source, so as to react with the silicon substrate in a high-temperature environment to form aluminum-silicon alloys and a back surface field (BSF) layer and therefore reduce the likelihood of recombination of minority carriers on the back side.

To enhance the optimal efficiency of solar cells, solar cell manufacturers launched the local back surface field (LBSF) technology from 2013. LBSF, also known as passivated emitter and rear contact (PERC), entails plating at least two oxide layers (composed of a bottom oxide layer and a cap oxide layer) by film plating. The bottom oxide layer is adapted to repair any defects on the surface of the silicon chip. The cap oxide layer not only protects the bottom oxide layer against any damage otherwise caused by aluminum pastes but also promotes optical reflection. Upon completion of the film plating process performed on the two oxide layers, openings, which are aligned with parallel lines spaced apart by a distance of 30˜40 μm or each have a diameter of 200 μm and thus are dot-shaped, are formed in the two oxide layers by laser or acid etching. Afterward, the openings of the two oxide layers are coated with an aluminum paste, and then the two oxide layers are delivered to a rapid high-temperature sintering furnace for cofiring. The aforesaid technology is known as the LBSF technology, because the aluminum paste is formed at the openings only.

The LBSF technology is confronted with a major technical problem as follows: conventional aluminum pastes are excessively corrosive to the bottom oxide layer and the cap oxide layer, and in consequence the bottom oxide layer's capability of repairing a defect gets lessened or even lost. However, attempts to reduce the corrosiveness of aluminum pastes are always accompanied by a decrease in the aluminum pastes' adhesion to the cap oxide layer.

To solve the aforesaid problem, aluminum paste manufacturers devised aluminum pastes which manifest relatively less corrosiveness. For instance, CN 103545013, US 2011120535 A1, and US 2013183795 A1 disclose a glass powder with a high lead content to thereby enhance the aluminum pastes' attachment to a cap oxide layer, because lead oxide (PbO) melts readily to decompose and thus manifests high reactivity.

Although conventional aluminum pastes are lead-free, the aforesaid aluminum pastes intended for use in a LBSF-based process require a glass powder with a high lead content and thus go against the current environmental protection trend and safety standards. Accordingly, it is imperative to provide a conductive aluminum paste intended for use in a LBSF-based process and adapted to keep photoelectric conversion efficiency and pulling strength unchanged in spite of its reduced lead oxide content.

### SUMMARY OF THE INVENTION

In view of the aforesaid drawbacks of the prior art, it is an objective of the present invention to provide a conductive aluminum paste for a local back surface field (LBSF) solar cell and a solar cell requiring the conductive aluminum paste with a view to keeping the photoelectric conversion efficiency of the solar cell and pulling strength unchanged in spite of its reduced lead oxide content.

In order to achieve the above and other objectives, the present invention provides a conductive aluminum paste for LBSF solar cell. The conductive aluminum paste comprises: an aluminum powder; an organic carrier including a resin and a solvent; and a vanadium oxide.

The conductive aluminum paste includes the vanadium oxide directly, and the vanadium oxide accounts for a maximum of 1.5% of a total weight of the conductive aluminum paste.

As regards the conductive aluminum paste, a vanadium oxide-containing glass powder is introduced such that the conductive aluminum paste contains the vanadium oxide.

As regards the conductive aluminum paste, the vanadium oxide accounts for a maximum of 75% of a total weight of the glass powder.

As regards the conductive aluminum paste, the glass powder accounts for a maximum of 10% of a total weight of the conductive aluminum paste.

As regards the conductive aluminum paste, the glass powder accounts for a maximum of 3% of the total weight of the conductive aluminum paste.

As regards the conductive aluminum paste, the aluminum powder accounts for 65˜75% of the total weight of the conductive aluminum paste.

As regards the conductive aluminum paste, the aluminum powder preferably comprises: a fine aluminum powder with a particle diameter less than 3 μm; and a coarse aluminum powder with a particle diameter of 3˜8 μm, wherein the fine aluminum powder accounts for a maximum of 30% of a total weight of the conductive aluminum paste.

As regards the conductive aluminum paste, the fine aluminum powder preferably accounts for 5˜25 wt % of the total weight of the conductive aluminum paste.

As regards the conductive aluminum paste, the organic carrier preferably accounts for 10˜30% of the total weight of the conductive aluminum paste.

As regards the conductive aluminum paste, the organic carrier preferably accounts for 20˜28% of the total weight of the conductive aluminum paste.

As regards the conductive aluminum paste, the organic carrier comprises: a resin selected from the group consisting of ethyl cellulose, wood rosin, and polyacrylonitrile; and a solvent.

The conductive aluminum paste further comprises an additive selected from the group consisting of a dispersing agent, a leveling agent, a defoaming agent, a suspending agent, a thixotropy promoter, and a coupling agent.

In order to achieve the above and other objectives, the present invention further provides a solar cell which comprises the conductive aluminum paste.

The present invention provides a conductive aluminum paste for a local back surface field solar cell and a solar cell requiring the conductive aluminum paste with a view to enhancing the photoelectric conversion efficiency of the local back surface field solar cell and the pulling strength even though its lead content is reduced or it is lead-free.

### DETAILED DESCRIPTION OF THE PREFERRED EMBODIMENTS

Objectives, features, and advantages of the present invention are hereunder illustrated with specific embodiments and described below.

A conductive aluminum paste provided by the present invention essentially comprises an aluminum powder, an organic carrier, and a vanadium oxide, and may further comprise a glass powder and various additives.

The aluminum powder accounts for 65˜80%, preferably 70˜76%, of the total weight of the conductive aluminum paste.

The aluminum powder preferably comes in at least two particle sizes. For example, the aluminum powder is generally composed of a fine aluminum powder and a coarse aluminum powder. When the fine aluminum powder has a particle diameter less than 3 μm, the coarse aluminum powder has a particle diameter of 3˜8 μm. The fine aluminum powder preferably accounts for less than 30 wt % of the total weight of the conductive aluminum paste and preferably accounts for 5˜25 wt % of the total weight of the conductive aluminum paste.

According to the present invention, the vanadium oxide (V₂O₅) is adapted to augment the attachment of the conductive aluminum paste to a substrate and control the reactivity of the conductive aluminum paste. The vanadium oxide is provided in the form of oxides in order to be introduced directly into the conductive aluminum paste so as to operate in conjunction with a lead-free glass powder or a lead-containing glass powder, thereby reducing the required amount of the lead-containing glass powder in use. It is also practicable to introduce a vanadium oxide-containing glass powder into a reactor, such that the conductive aluminum paste of the present invention comprises a vanadium oxide. The glass powder is produced by melting multiple elements or compounds at high temperature. The glass powder comprises the vanadium oxide, and the vanadium oxide preferably accounts for a maximum of 75 wt % of the total weight of the glass powder.

For instance, the vanadium oxide, zinc oxide, phosphorus oxide, and antimony oxide are melted at high temperature to produce vanadium oxide-containing glass powder V₂O₅—ZnO—P₂O₅—Sb₂O₃. The glass powder has an average particle diameter of less than 6.0 μm and accounts for 0˜10 wt %, preferably a maximum of 3 wt %, of the total weight of the conductive paste.

The organic carrier is adapted to provide screen printability and dryness intensity. It is produced by mixing at least a resin and at least an organic solvent. The resin is ethyl cellulose, wood rosin, or polyacrylonitrile , but the present invention is not limited thereto. The solvent is an ester alcohol film-forming agent (TEXANOL®, EASTMAN CHEMICAL COMPANY), terpineol, or di(ethylene glycol) monobutyl ether, but the present invention is not limited thereto. The organic carrier accounts for 10˜30 wt %, and preferably 20˜28 wt %, of the total weight of the conductive aluminum paste.

The additive is adapted to increase the stability, printability, flatness, reactivity, and powder adhesion of an aluminum paste and provided in the form of a dispersing agent, a leveling agent, a defoaming agent, a suspending agent, a thixotropy promoter, and a coupling agent, but the present invention is not limited thereto. The additives together account for 0˜5 wt %, and preferably 0˜1.3 wt %, of the total weight of the conductive aluminum paste.

The conductive aluminum pastes according to embodiments 1˜4 and comparisons 1˜4 of the present invention are prepared in accordance with the ingredients and percentages stated in Table 1 and Table 2. Referring to Table 1, the vanadium oxide is not introduced into the reactor directly, wherein, in embodiment 1, a vanadium oxide-containing glass powder is introduced into the reactor in order for the conductive aluminum paste to include the vanadium oxide. Referring to Table 2, the vanadium oxide is included directly in the conductive aluminum pastes.

TABLE 1

| ingredient | material source | embodiment 1 | comparison 1 | comparison 2 | comparison 3 |
|---|---|---|---|---|---|
| organic carrier | 15% ETHOCEL Std 20 + 20% | 24.0% | 24.0% | 24.0% | 24.0% |
| | terpineol + 65% di(ethylene | | | | |
| | glycol) monobutyl ether | | | | |
| PbO-containing | PANCOLOUR ® PCI-W3781 | | 2.40% | | |
| glass powder | (PbO—B₂O₃—SiO₂—Al₂O₃) | | | | |
| PbO-containing | PANCOLOUR ® PCI-W3793 | | | 2.40% | |
| glass powder | (PbO—B₂O₃—ZnO—TiO₂—SiO₂) | | | | |
| V₂O₅-containing | PANCOLOUR ® PCI-W3807 | | | | 2.40% |
| glass powder | (80% V₂O₅—B₂O₃—SiO₂—ZnO) | | | | |
| V₂O₅-containing | PANCOLOUR ® PCI-W3801 | 2.40% | | | |
| glass powder | (55% V₂O₅—B₂O₃—SiO₂—ZnO) | | | | |
| Bi₂O₃-containing | PANCOLOUR ® PCI-W3799 | | | | |
| glass powder | (Bi₂O₃—ZnO—B₂O₃—SiO₂) | | | | |
| V₂O₅ | Aldrich Chemical | | | | |
| fine aluminum | Hunan Goldhorse FO103 | 14.70% | 14.70% | 14.70% | 14.70% |
| powder | | | | | |
| coarse aluminum | Hunan Goldhorse JM607 | 58.70% | 58.70% | 58.70% | 58.70% |
| powder | | | | | |
| promoter | 0.2% Elementis Specialties | 0.20% | 0.20% | 0.20% | 0.20% |
| | Thiaxatrol ST | | | | |
| total | | 100.0% | 100.0% | 100.0% | 100.0% |

TABLE 2

| ingredient | material source | embodiment 2 | embodiment 3 | embodiment 4 | comparison 4 |
|---|---|---|---|---|---|
| organic carrier | 15% ETHOCEL Std 20 + 20% | 24.00% | 24.00% | 24.00% | 24.0% |
| | terpineol + 65% di(ethylene | | | | |
| | glycol) monobutyl ether | | | | |
| PbO-containing | PANCOLOUR ® PCI-W3781 | | | 1.20% | |
| glass powder | (PbO—B₂O₃—SiO₂—Al₂O₃) | | | | |
| PbO-containing | PANCOLOUR ® PCI-W3793 | | | | |
| glass powder | (PbO—B₂O₃—ZnO—TiO₂—SiO₂) | | | | |
| V₂O₅-containing | PANCOLOUR ® PCI-W3807 | | | | |
| glass powder | (80% V₂O₅—B₂O₃—SiO₂—ZnO) | | | | |
| V₂O₅-containing | PANCOLOUR ® PCI-W3801 | | 2.30% | | |
| glass powder | (55% V₂O₅—B₂O₃—SiO₂—ZnO) | | | | |
| Bi₂O₃-containing | PANCOLOUR ® PCI-W3799 | 2.40% | | | 2.40% |
| glass powder | (Bi₂O₃—ZnO—B₂O₃—SiO₂) | | | | |
| V₂O₅ | Aldrich Chemical | 0.90% | 0.90% | 1.50% | 2.00% |
| fine aluminum | Hunan Goldhorse FO103 | 14.70% | 14.70% | 14.70% | 14.70% |
| powder | | | | | |
| coarse aluminum | Hunan Goldhorse JM607 | 57.80% | 57.90% | 58.40% | 56.70% |
| powder | | | | | |
| promoter | 0.2% Elementis Specialties | 0.20% | 0.20% | 0.20% | 0.20% |
| | Thiaxatrol ST | | | | |
| total | | 100.0% | 100.0% | 100.0% | 100.0% |

### Embodiment 1

The conductive aluminum paste of embodiment 1 is prepared by following the steps as follows:

Step 1 (of producing an organic carrier): ethyl cellulose (ETHOCEL Std 20)/terpineol/di(ethylene glycol) monobutyl ether (at a ratio of 15:20:65) is introduced into a reactor and then blended in an oil bath at 110° C., at 300 rpm, and for at least three hours until it is completely dissolved.

Step 2: a vanadium oxide-containing glass powder, an aluminum powder, and other related ingredients are included in the organic carrier produced in step 1 in accordance with the ingredients and percentages stated in Table 1 to prepare 300 g of blended aluminum paste.

Step 3: the blended aluminum paste prepared in step 2 is further blended with a high-speed blender for three minutes so that it is thoroughly blended; then, it is ground thrice with a three-roll grinder (model number: Exakt 80E) such that the ground conductive aluminum paste attains viscosity of 30˜50 Pa·s and average particle diameter of 6 μm.

### Embodiments 2˜4 and Comparisons 1˜4

The conductive aluminum pastes of embodiments 2˜4 and comparisons 1˜4 are prepared by following the same steps as that of embodiment 1, except that step 2 entails changing the ingredients and percentages stated in Table 1 and Table 2, respectively.

Test

Solar cells are made from the conductive aluminum pastes produced according to embodiments 1˜4 and comparisons 1˜4 by following the steps as follows:

Step 1 (printing): a back-side silver paste and a front-side silver paste are imprinted on the back side and the front-side of a silicon substrate for a LBSF semi-finished product (front-side SiNx, back-side with 6 nm Al₂O₃ bottom oxide layer disposed thereon +80 nm SiNx cap oxide layer), respectively, by screen printing, and then dried in an oven at 200° C.; afterward, a portion of the back side of the silicon substrate, which is not covered with the back-side silver paste, is imprinted with the conductive aluminum pastes produced in embodiments 1˜4 and comparisons 1˜4, wherein the conductive aluminum pastes each overlap the back-side silver paste; adjustments are made to the printing parameters and the number of screen meshes so as to controllably set the printing weight to 1.1 g; afterward, the silicon substrate is put in the oven again in order to be dried therein at 200° C. for three minutes, and in consequence a printing silicon substrate to be sintered is produced.

Step 2 (sintering): upon completion of the drying step, the would-be-sintered printing silicon substrate produced in step 1 is put in a despatch CF furnace for undergoing a sintering step to manufacture a solar cell. In the sintering step, related parameters are set to Z1/Z2/Z3/Z4/Z5/Z6/speed=500° C./550° C./600° C./680° C./830° C./930° C./230 ipm; the despatch CF furnace conveys the would-be-sintered printing silicon substrate by means of a conveyor belt , such that the would-be-sintered printing silicon substrate passes through different temperature zones Z1˜Z6, wherein the maximum conveyance speed of the conveyor belt is 230 ipm (inch/minute).

Given the aforesaid steps, solar cells are made from the conductive aluminum pastes prepared in embodiments 1˜4 and comparisons 1˜4, respectively, and they are tested in terms of the following properties.

Solar photovoltaic conversion efficiency: simulate a test system with a solar cell plate to test the filling factor (FF (%)), open-circuit voltage (Voc(mv)), and solar photovoltaic conversion efficiency (%) of the solar cell, wherein the test instrument is QuickSun 120CA manufactured by Finland-based Endeas.

Pull: cut EVA film into 1 cm×10 cm strips, put the EVA film strips on the back of the solar cell, allow the EVA film strips on the back of the solar cell to undergo a hot-pressing process thrice at 150° C. with a laminator, such that the EVA film strips are hot-pressed against the back of the solar cell, measure and determine the maximum pull between the EVA film and the solar cell with a pull gauge. If the maximum pull is determined to be less than 10N, the solar cell will be deemed defective.

Water tolerance: put 500 cc of deionized water in a beaker, heat the beaker on a heating plate until the water temperature reaches 75° C., and put the solar cell flat at the bottom of the beaker. If bubbles last for 10 minutes, the solar cell will be deemed defective.

Warpage: after being sintered, the solar cell is cooled down for 1 hour, and then its thickness is measured with a thickness gauge; if its thickness is found to be more than 1.8 mm, the solar cell will be deemed defective.

Aluminum bump: after being sintered, the solar cell has its surface marked by bumps similar in appearance to that found on the skins of Citrus fruits. The presence of aluminum bumps on the surface of the solar cell indicates that the solar cell is defective.

The test results of the aforesaid properties are presented in Table 3 and Table 4 in which unsatisfactory results of the tests are indicated by boldface.

TABLE 3

| | embodiment 1 | | | comparison 3 |
|---|---|---|---|---|
| | (using 55% | comparison 1 | comparison 2 | (using 80% |
| | vanadium | (using | (using | vanadium |
| | oxide-containing | lead-containing | lead-containing | oxide-containing |
| property | glass powder) | glass powder) | glass powder) | glass powder) |
| photovoltaic | 20.38 | 20.30 | 20.28 | 20.32 |
| conversion | | | | |
| efficiency (%) | | | | |
| Voc (mv) | 646.3 | 644.4 | 645.3 | 645.2 |
| FF (%) | 78.9 | 78.9 | 78.8 | 78.9 |
| pull (N) | 23 | 9 | 8 | 21 |
| water tolerance | OK | NG | NG | OK |
| warpage | OK | OK | OK | NG |
| aluminum bump | OK | NG | NG | NG |

TABLE 4

| | embodiment 2 | embodiment 3 | embodiment 4 | comparison 4 |
|---|---|---|---|---|
| | (including 0.9% | (including 0.9% | (including 1.5% | (including 2.0% |
| | vanadium oxide | vanadium oxide | vanadium oxide | vanadium oxide |
| property | directly) | directly) | directly) | directly) |
| photovoltaic | 20.37 | 20.40 | 20.39 | 20.21 |
| conversion | | | | |
| efficiency (%) | | | | |
| Voc (mv) | 646.5 | 646.7 | 646.4 | 644.3 |
| FF (%) | 78.9 | 78.8 | 79.0 | 78.8 |
| pull (N) | 20 | 21 | 22 | 25 |
| water tolerance | OK | OK | OK | OK |
| warpage | OK | OK | OK | NG |
| aluminum bump | OK | OK | OK | NG |

The test results shown in Table 3 reveal the following: embodiment 1 and comparison 3, which use the vanadium oxide-containing glass powder, equal or slightly outperform comparison 1 and comparison 2 which use the lead-containing glass powder in terms of photovoltaic conversion efficiency (%), open-circuit voltage (Voc(mv)), and filling factor (FF (%)); embodiment 1 and comparison 3 outperform comparison 1 and comparison 2 evidently in terms of pull, thereby showing that the use of the vanadium oxide-containing glass powder enhances the pull of the solar cell thus manufactured. A further contrast and comparison in the ingredient proportions and test results between embodiment 1 and comparison 3 reveals the following: comparison 3 use 80% vanadium oxide-containing glass powder and in consequence cause warpage and aluminum bumps; on the contrary, embodiment 1 uses 55% vanadium oxide-containing glass powder and thus does not cause any warpage and aluminum bumps. Hence, to allow the conductive aluminum pastes of the present invention to include a vanadium oxide by including a vanadium oxide-containing glass powder, it is necessary that the vanadium oxide accounts for a maximum of 75 wt % of the glass powder.

In addition, the test results shown in Table 4 reveal the following: with 0.9˜1.5% vanadium oxide being included directly (in embodiments 2˜4), the further introduction of a bismuth oxide-containing glass powder (in embodiment 2), a vanadium oxide-containing glass powder (in embodiment 3), and a lead oxide-containing glass powder (in embodiment 4) enhances the photoelectrical properties, pull, and water tolerance of the solar cells thus manufactured but does not cause warpage and aluminum bumps. A further contrast and comparison in the ingredient proportions and test results between embodiment 2 and comparison 4 reveals the following: comparison 4 features including 2.0% vanadium oxide directly and thus causing warpage and aluminum bumps; on the contrary, embodiment 2 features including 0.9% vanadium oxide directly and thus not causing any warpage and aluminum bumps. Hence, to include the vanadium oxide directly, it is necessary that vanadium oxide accounts for a maximum of 1.5% of the total weight of the conductive aluminum paste.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A conductive aluminum paste for a local back surface field solar cell, the conductive aluminum paste comprising:
an aluminum powder;
an organic carrier including a resin and a solvent; and
a vanadium oxide.

2. The conductive aluminum paste of claim 1, wherein the vanadium oxide is directly introduced, and the vanadium oxide accounts for a maximum of 1.5% of a total weight of the conductive aluminum paste.

3. The conductive aluminum paste of claim 1, wherein a vanadium oxide-containing glass powder is introduced such that the conductive aluminum paste contains the vanadium oxide.

4. The conductive aluminum paste of claim 3, wherein the vanadium oxide accounts for a maximum of 75% of a total weight of the glass powder.

5. The conductive aluminum paste of claim 3, wherein the glass powder accounts for a maximum of 10% of a total weight of the conductive aluminum paste.

6. The conductive aluminum paste of claim 5, wherein the glass powder accounts for a maximum of 3% of the total weight of the conductive aluminum paste.

7. The conductive aluminum paste of claim 1, wherein the aluminum powder accounts for 65˜75% of the total weight of the conductive aluminum paste.

8. The conductive aluminum paste of claim 7, wherein the aluminum powder comprises:
a fine aluminum powder with a particle diameter less than 3 μm; and
a coarse aluminum powder with a particle diameter of 3˜8 μm,
wherein the fine aluminum powder accounts for a maximum of 30% of the total weight of the conductive aluminum paste.

9. The conductive aluminum paste of claim 1, further comprising an additive selected from the group consisting of a dispersing agent, a leveling agent, a defoaming agent, a suspending agent, a thixotropy promoter, and a coupling agent.

10. A solar cell, comprising the conductive aluminum paste of claim 1.
